(19) United States
(12) Patent Application Publication
(10) Pub. No.: US 2024/0174919 A1
(43) Pub. Date: May 30, 2024

(54) Quantum Dots, Methods For Preparing Quantum Dots, And Electronic Devices

(71) Applicant: Duk San Neolux Co., Ltd., Cheonan-si (KR)

(72) Inventors: Han Byule LIM, Cheonan (KR); Chang Min Lee, Cheonan (KR); Jong Moon Shin, Cheonan-si (KR); Kyung Soo Kim, Cheonan (KR)

(21) Appl. No.: 18/517,722

(22) Filed: Nov. 22, 2023

(30) Foreign Application Priority Data
Nov. 24, 2022 (KR) 10-2022-0159415

(51) Int. Cl. C09K 11/62; H10K 50/115

(52) U.S. Cl. CPC C09K 11/621; H10K 50/115; B82Y 20/00

(57) ABSTRACT

An embodiment of the disclosure provides AgInGaS quantum dots, a method for preparing the same, and an electronic device capable of controlling the emission wavelength according to the composition of Ag, In, and Ga precursors constituting a quantum dot core.

### CROSS-REFERENCE TO RELATED APPLICATION

This application claims priority from Korean Patent Application No. 10-2022-0159415, filed on Nov. 24, 2022, which is hereby incorporated by reference for all purposes as if fully set forth herein.

### BACKGROUND

### Field

The disclosure relates to quantum dots, methods for preparing quantum dots, and electronic devices.

### Description of Related Art

A quantum dot is a material with a size of a few nanometers that, due to quantum confinement effects, exhibits different properties than the material in its bulk state. Quantum dots have different wavelengths of light emission depending on the intrinsic bandgap of the material.

Quantum dots are generally composed of a core and a shell, and the core is the main element that determines the properties of the quantum dot, such as the emission wavelength and half- width of the quantum dot. These optical properties are a special phenomenon at the scale of a few nanometers, and due to quantum confinement effects, are different from those of the material in the bulk state. By the properties, quantum dots may emit light in different colors as their emission wavelength is controlled depending on the particle size in the same composition. Further, quantum dots may emit light in a wide range of wavelengths, not only in the visible spectrum, making them a promising material for next-generation high-brightness light emitting diodes (LEDs), biosensors, lasers, and solar cell nanomaterials.

The emission wavelength of quantum dots may be controlled in various ways based on the material's intrinsic bandgap.

The emission wavelength of quantum dots may be controlled by adjusting the particle size because quantum dots generally exhibit a tendency to increase the bandgap as the particle size decreases, resulting in a blue-shifted emission wavelength, and conversely, decrease the bandgap as the particle size increases, resulting in a relatively red-shifted emission wavelength. However, it is hard to control the particle size in methods for fabricating the previously studied quantum dots based on III-V group compounds, and it is particularly difficult to construct quantum dots with a blue- shifted emission wavelength by reducing the particle size.

Therefore, in recent years, quantum dot technologies for I-III-VI group displays have been developed in addition to quantum dots based on III-V group compounds.

Quantum dots for I-III-VI group displays have the advantage of relatively high luminous efficiency due to their larger absorbance compared to III-V group quantum dots. Further, among the I-III-VI group quantum dots, AgInGas quantum dots are a four-component system, which makes it easy to change the luminescence characteristics according to the composition of the elements that make up the quantum dots. Accordingly, it may be used as a quantum dot material with excellent color reproduction by variously adjusting the emission wavelength according to the composition change.

Therefore, there is a need for a technology that may control optical properties such as emission wavelength by appropriately adjusting the composition of AgInGaS quantum dots.

### BRIEF SUMMARY

In one aspect, embodiments of the disclosure provide AgInGaS quantum dots, a quantum dot preparing method, and an electronic device capable of controlling the emission wavelength by controlling the amounts of Ag, In, and Ga precursors when forming an AgInGaS quantum dot core.

An embodiment of the disclosure provides AgInGaS quantum dots, a quantum dot preparing method, and an electronic device capable of adjusting the emission wavelength in a range of 500 nm to 580 nm according to the amounts of Ag, In, and Ga precursors in forming an AgInGaS quantum dot core.

In an aspect, embodiments of the disclosure provide a quantum dot comprising a core including Ag, In, Ga, and S, and a shell including at least one selected from among a group I element or a group III element and a group VI element on the core.

The quantum dot is capable of adjusting an emission wavelength according to a ratio of Ag, In, and Ga precursors defined by Equation 1.

$$\frac{In precursor ( mol )}{Ag precursor ( mol ) + Ga precursor ( mol )} = X \qquad [ Equation 1 ]$$

in Equation 1,
1) the amount of the precursor of each element is 0.1 mmol or more,
2) when X is 0.32 or more and less than 0.40, the quantum dot has an emission wavelength of 500 nm to 530 nm, and
3) when X is 0.40 or more and less than 0.60, the quantum dot has an emission wavelength of 531 nm to 580 nm.

The at least one group I element included in the shell may include at least one selected from among Li, Na, K, Rb, Cs, Cu, Ag, and Au.

The at least one group III element included in the shell may include at least one selected from among Al, Ga, In, and Tl.

The at least one group VI element included in the shell may include at least one selected from among S, Se, and Te.

The quantum dot may have a diameter of 1 nm to 20 nm.

The shell may include a first shell disposed on the core and including at least one of a group I element and a group III element and a group VI element and a second shell disposed on the first shell and including at least one of a group I element and a group III element and a group VI element. The group I elements and group III elements, and group VI elements included in the first shell and the second shell may be the same or different.

The first shell may include one of AgAIS, AgAlSe, AgAlTe, AgGaS, AgGaSe, AgGaTe, AgInS, AgInSe, AgInTe, AgTiS, AgTiSe, AgTiTe, CuAls, CuAlSe, CuAlTe, CuGaS, CuGaSe, CuGaTe, CuInS, CuInSe, CuInTe, CuTis, CuTiSe, CuTiTe, AuAlS, AuAlSe, AuAlTe, AuGaS, AuGaSe, AuGaTe, AuInS, AuInSe, AuInTe, AuTiS, AuTiSe, and AuTiTe.

The second shell may include one of Als, AlSe, AlTe, Gas, GaSe, GaTe, InS, InSe, InTe, TiS, TiSe, and TiTe.

In another aspect, embodiments of the disclosure provide a method for preparing quantum dots.

The quantum dot preparing method includes a core preparing step and a shell preparing step.

The core preparing step is the step of preparing a core by injecting and reacting an Ag precursor, an In precursor, a Ga precursor, an S precursor, and a solvent in a first reactor.

The shell preparing step is the step of preparing a shell by injecting and reacting the prepared core in a second reactor containing at least one selected from among a group I precursor including a group I element or a group III precursor including a group III element and a group VI precursor including a group VI element.

The quantum dot is capable of adjusting an emission wavelength according to a ratio of Ag, In, and Ga precursors defined by Equation 1 described above.

In another aspect, embodiments of the disclosure provide an electronic device comprising a display device including a light emitting diode including a quantum dot and a controller driving the display device.

### DESCRIPTION OF DRAWINGS

The above and other aspects, features, and advantages of the disclosure will be more clearly understood from the following detailed description, taken in conjunction with the accompanying drawings, in which:

FIG. 1 is a cross-sectional view illustrating a quantum dot according to an embodiment ;

FIG. 2 is a cross-sectional view illustrating a quantum dot according to another embodiment ;

FIG. 3 is a cross-sectional view illustrating a quantum dot according to another embodiment ;

FIG. 4 is a cross-sectional view illustrating an electronic device according to another embodiment; and

FIG. 5 is a cross-sectional view illustrating an LED according to another embodiment.

### DETAILED DESCRIPTION

Hereinafter, the following description focuses only on parts necessary for understanding embodiments, and a method for preparing quantum dots is described in detail. Unless defined otherwise, the terms used herein should be interpreted as understood by those of ordinary skill in the art to which this disclosure pertains. When determined to make the subject matter of the disclosure unclear, the detailed description of the known art or functions may be skipped.

Such denotations as “first, ” “second, ” “A, ” “B, ” “(a),” and “(b),” may be used in describing the components of the disclosure. These denotations are provided merely to distinguish a component from another, and the essence of the components is not limited by the denotations in light of order or sequence. When a component is described as “connected, ” “coupled, ” or “linked” to another component, the component may be directly connected or linked to the other component, but it should also be appreciated that other components may be “connected, ” “coupled, ” or “linked” between the components.

When a component is “on” or “above” another component, it should be understood that the component may be immediately on or above the other component, or other components may intervene therebetween. In contrast, when a component is “immediately on” another component, it should be understood that no intervening component is present therebetween. Further, when a component is “on” or “above” another component, the component may be positioned above or under the other component, but not necessarily means that the component is “on” or “above” the other component in the direction opposite to the direction of gravity.

When an element “includes” another element, the element may further include the other element, rather excluding the other element, unless particularly stated otherwise.

When an element is viewed “in plan view,” it means that the element is viewed from thereabove, and when an element is viewed “in cross-sectional view,” it means that a cross section of the element is viewed.

As used herein, the term “group” means the group of the periodic table of elements.

As used herein, “group I” may include group IA and group IB, and group I elements include, but are not limited to, Li, Na, K, Rb, Cs, Cu, Ag, and Au.

“Group II” may include group IIA and group IIB, and group II elements include, but are not limited to, Be, Mg, Ca, Sr, Zn, Cd, and Hg.

“Group III” may include group IIIA and group IIIB, and group III elements include, but are not limited to, In, Ga, and Al.

“Group V” may include group VA, and group V elements include, but are not limited to, P, As, Sb, Bi, and N.

“Group VI” may include group VIA, and group VI elements include, but are not limited to, S, Se, and Te.

As used herein, the term “precursor” is a chemical substance previously prepared to react quantum dots, and is a concept denoting all compounds including metals, ions, elements, compounds, complexes, or clusters. It is not necessarily limited to the final material of any reaction, and means a material that may be obtained at any stage arbitrarily determined.

Hereinafter, quantum dots according to embodiments of the disclosure are described below with reference to the accompanying drawings.

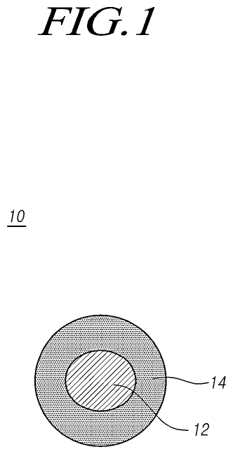

FIG. 1 is a cross-sectional view illustrating a quantum dot according to an embodiment.

Referring to FIG. 1, a quantum dot 10 according to the disclosure includes an AgInGaS quantum dot core 12 including Ag, In, Ga and S.

The quantum dot 10 according to the disclosure may be an AgInGaS quantum dot including the AgInGaS core 12 and a shell 14 disposed on the AgInGaS core 12.

In one embodiment, the shell 14 disposed on the core 12 may include at least one selected from among group I elements or group III elements and a group VI element.

Group I elements used in the shell 14 may include group IA and group IB, and one selected from the group consisting of Li, Na, K, Rb, Cs, Cu, Ag, and Au or a combination thereof may be used, but is not limited thereto.

Group III elements used in the shell 14 may include group IIIA and group IIIB, and one selected from the group consisting of In, Ga, Al, and Tl or a combination thereof may be used, but is not limited thereto.

Group VI elements used in the shell 14 may be selected from the group consisting of S, Se, and Te, or a combination thereof, but is not limited thereto.

In one embodiment, the quantum dot 10 of the disclosure composed of a light emitter may be a type 1 quantum dot according to the band gap difference between the core 12 and the shell 14.

The type 1 quantum dot is a quantum dot having a structure in which the band gap of the shell 14 is larger than the band gap of the core 12, and in the corresponding structure, light emission occurs in the core 12 having a smaller band gap, and the shell 14 does not affect light emission. Therefore, the emission wavelength is affected only by the configuration of the core 12.

In the type 1 structure, the shell 14 serves to suppress a surface defect of the core 12, and accordingly, luminous efficiency may be further enhanced.

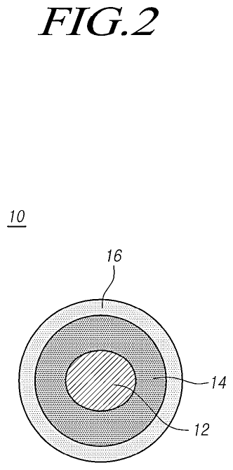

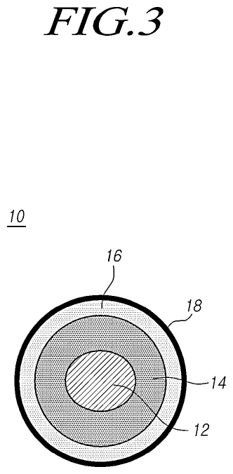

FIG. 2 is a cross-sectional view illustrating a quantum dot according to another embodiment. FIG. 3 is a cross-sectional view illustrating a quantum dot according to another embodiment.

Referring to FIG. 2, in an embodiment, a quantum dot 10 may have a core-multilayer shell structure having an AgInGaS core 12, a first shell 14 including at least one of a group I element and a group III element disposed on (or directly on) the core 12 and a second shell 16 including at least one of a group I element and a group III element and a group VI element disposed on (directly on) the first shell.

As illustrated in FIG. 3, the quantum dot 10 according to other embodiments may include the AgInGaS core 12, the first shell 14, and the second shell 16, and may further include another shell 18 outside the second shell 16 or may further include another intermediate shell (not shown) between the first shell 14 and the second shell 16.

In one embodiment, the AgInGaS core shell quantum dot may be prepared by forming the AgInGaS core 12 using an Ag precursor, an In precursor, a Ga precursor, and an S precursor in a reactor and forming the first shell 14 on the core by injecting at least one of the group I element and the group III element constituting the first shell 14 and a group VI element precursor into the AgInGaS core 12, or forming the second shell 16 by injecting at least one of the group I element and the group III element and the group VI element precursor into the quantum dot solution where the first shell 14 is formed.

The group III and group VI elements included in the first shell 14 and the second shell 16 may be the same or different. The AgInGaS core shell quantum dot forming method may be performed by a hot-injection method, an in-situ method, and a heating up method. The above-described methods may be performed in each step of the AgInGaS core preparing step and the shell preparing step.

The Ag precursor constituting the core 12 may be, e.g., at least one selected from the group consisting of silver (I) acetylacetonate, silver (I) chloride, silver (I) bromide, silver (I) iodide, silver (I) acetate, silver (I) nitrate, and silver (I) myristate.

The In precursor constituting the core 12 may be, e.g., at least one selected from the group consisting of indium (II) acetylacetonate, indium (III) chloride, Indium (II) acetate, trimethyl Indium, alkyl Indium, aryl Indium, indium (II) myristate, and indium (MI) myristate acetate.

The Ga precursor constituting the core 12 may be, e.g., at least one selected from the group consisting of gallium (III) acetylacetonate, gallium (II) chloride, gallium (MI) iodide, gallium (II) bromide, gallium (II) acetate, and gallium (II) nitrate.

The S precursor constituting the core 12 may be, e.g., at least one selected from the group consisting of 1-octanethiol, 1-dodecanethiol, sulfur dichloride (SC12), sulfur (S), S-TOP, and S-ODE.

The Ag, In, Ga, and S precursors constituting the core 12 may be mixed with a solvent, such as oleylamine, ethanol, and toluene, to be constituted as a precursor-solvent precursor solution for preparing the AgInGaS quantum dot core.

In an embodiment, the group I precursor constituting the shell 14 may include, but is not limited to, an Ag precursor, a Cu precursor, or an Au precursor.

The Cu precursor constituting the shell 14 may be, e.g., at least one selected from a group consisting of cupper (II) acetylacetonate, cupper (II) chloride, cupper (II) bromide, cupper (II) iodide, cupper (II) acetate, and cupper (II) nitrate. The Au precursor constituting the shell 14 may be, e.g.,

at least one selected from the group consisting of, e.g., hydrogen tetrachloroaurate (III), gold (III) chloride, and gold (III) bromide.

The Ag precursor constituting the shell 14 has already been described in connection with the precursor constituting the core 12, and thus a description thereof will be omitted.

The group III precursor constituting the shell 14 may include, but are not limited to, a Ga precursor, an In precursor, an Al precursor, or a Tl precursor.

The Ga precursor and the In precursor constituting the shell 14 have already been described in connection with the precursors constituting the core, and thus a description thereof will be omitted.

The Al precursor may be, e.g., at least one selected from the group consisting of compounds such as aluminum (III) chloride, aluminum (III) iodide, aluminum oxide, and aluminum acetylacetonate.

The Tl precursor may be, e.g., one selected from the group consisting of compounds such as thallium acetate, thallium acetylacetone, thallium oxide, thallium bromide, thallium chloride, and thallium iodide.

The group VI precursor constituting the shell 14 may include, but is not limited to, an S precursor, an Se precursor, and a Te precursor.

The Se precursor may be, e.g., at least one selected from the group consisting of selenium chloride, selenium (Se), Se-TOP, Se-DPP, Se-ODE, and organic selenium compounds, e.g., compounds such as dibenzyl diselenide, diphenyl diselenide, or selenium hydride.

The Te precursor may be, e.g., at least one selected from the group consisting of tellurium chloride, tellurium (Te), and tellurium hydride.

The first shell 14 and the second shell 16 each may include one of AgAIS, AgAlSe, AgAlTe, AgGaS, AgGaSe, AgGaTe, AgInS, AgInSe, AgInTe, AgTiS, AgTiSe, AgTiTe, CuAlS, CuAlSe, CuAlTe, CuGaS, CuGaSe, CuGaTe, CuInS, CuInSe, CuInTe, CuTiS, CuTiSe, CuTiTe, AuAlS, AuAlSe, AuAlTe, AuGaS, AuGaSe, AuGaTe, AuInS, AuInSe, AuInTe, AuTiS, AuTiSe, AuTiTe, Als, AlSe, AlTe, GaS, GaSe, GaTe, InS, InSe, InTe, TiS, TiSe, and TiTe.

In one embodiment, the molar ratio of the Ag, In, and Ga precursors constituting the AgInGaS core 12 in the AgInGaS quantum dot 10 is expressed by Equation 1 below.

$$\frac{In precursor ( mol )}{Ag precursor ( mol ) + Ga precursor ( mol )} = X \qquad [ Equation 1 ]$$

In Equation 1,
1) the amount of the precursor of each element is 0.1 mmol or more,
2) when X is 0.32 or more and less than 0.40, the quantum dot has an emission wavelength of 500 nm to 530 nm,
3) when X is 0.40 or more and less than 0.60, the quantum dot has an emission wavelength of 531 nm to 580 nm.

In Equation 1, as X is closer to 0, the AgInGaS quantum dot is blue-shifted in the emission wavelength, and as X is closer to 1, a red shift is possible.

The shape of the quantum dot 10 is one commonly used in the art and is not particularly limited. More specifically, the quantum dot 10 may be shaped as a spherical, pyramidal, multi-arm, or cubic nanoparticle, nanotube, nanowire, nanofiber, or nanoplatelet particle.

The quantum dot 10 may adjust the color of the emitted light according to the particle size, and accordingly, the quantum dot 10 may have various emission colors such as blue, red, and green.

According to an embodiment, the diameter of the quantum dot 10 may be 1 nm to 20 nm, preferably 2 nm to 15 nm, and more preferably 2 nm or more and 10 nm.

In another aspect of the disclosure, according to embodiments of the disclosure, there may be provided an ink composition of the quantum dot 10. In the ink composition according to embodiments of the disclosure, the quantum dot 10 is the same as the quantum dots according to embodiments of the disclosure unless otherwise described.

The ink composition according to the present embodiments may be a light conversion ink composition including quantum dots 10, a light curable monomer, a light initiator, and a light diffuser.

According to an embodiment, the content of the quantum dots 10 may be 20 parts by weight to 60 parts by weight, e.g., 25 parts by weight to 50 parts by weight, or 30 parts by weight to 45 parts by weight, with respect to the total content of 100 parts by weight of the quantum dot ink composition. According to an embodiment, the ink composition may not include a solvent. In other words, the ink composition may be a solvent-free quantum dot ink composition. According to an embodiment, the ink composition may have a viscosity of 10 cP to 25 cP. According to an embodiment, the surface tension of the ink composition at 25° C. may be 30 mN/m or more. When the above-described viscosity and/or surface tension range is satisfied, the ink composition, as a solvent-free quantum dot ink composition, may appropriately use various members, such as a color conversion member or an emission layer of an emission device, in a solution process such as an inkjet.

According to an embodiment, an optical member formed using an ink composition may be provided. For example, the optical member may be a color conversion member.

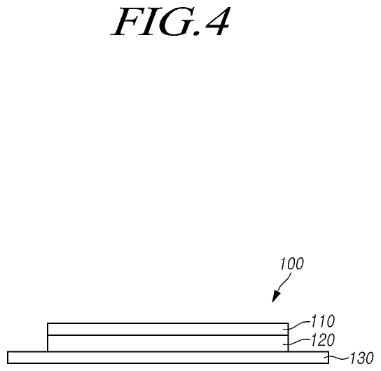

According to another aspect, referring to FIG. 4, an electronic device 100 according to an embodiment may include a substrate 110, a light source 120 disposed on the substrate 110, and a color conversion member 130 disposed in a path of light emitted from the light source 120, and the color conversion member 130 may be formed using the above-described ink composition.

According to an embodiment, the light source 120 may be an emission device. For example, the light source 120 may be an organic light emitting diode (OLED) or an inorganic light emitting diode (ILED or QLED).

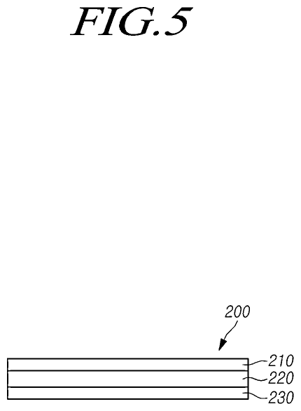

In another aspect, referring to FIG. 5, the light emitting diode 200 according to another embodiment may include quantum dots 10. The light emitting diode 200 according to other embodiments includes a positive electrode 210, a negative electrode 230, and an intermediate layer 220 positioned therebetween. The intermediate layer 220 may include an emission layer including an ink composition including the above-described quantum dots.

According to another aspect of the disclosure, there may be provided an electronic device including a display device including the above-described light emitting diode and a controller for driving the display device.

The electronic device may include, e.g., a display device, a lighting device, a solar cell, a portable or mobile terminal (e.g., a smartphone, a tablet, a PDA, an electronic dictionary, a PMP, etc.), a navigation terminal, a game console, various TVs, various computer monitors, etc., but without limitations thereto, may include any type of device that includes the component (s).

Applications to various electronic devices and devices using quantum dots may be easily applied by those skilled in the art, and thus detailed descriptions thereof will be omitted.

Hereinafter, specific embodiments are presented. However, the embodiments described below are merely for specifically illustrating or describing the disclosure, and the scope of the disclosure is not limited thereto.

### Embodiment

### (1) Preparation Example 1: Preparing Silver (I) Iodide-Oleylamine Precursor Solution

0.56 g (2.4 mmol) of silver (I) iodide and 10 mL (30 mmol) of oleylamine were placed in a 50 mL flask, decompressed at room temperature (RT) for 1 hour, heated to 120° C. for 10 minutes, and then reacted for 1 hour. The mixed solution was cooled to room temperature in in an Ar atmosphere to prepare an Ag precursor solution. The Ag concentration of the precursor solution is 0.24 M.

### (2) Preparation Example 2: Preparing Indium (III) Chloride-Ethanol Precursor Solution

0.11 g (0.5 mmol) of indium (III) chloride and 5 mL of ethanol were placed in 10 mL vial to prepare an In precursor solution. The In concentration of the precursor solution is 0.10 M.

### (3) Preparation Example 3: Preparing Gallium (III) Chloride-Toluene Precursor Solution

0.80 g (4.54 mmol) of gallium(III) chloride and 0.8 mL of toluene were placed in 10 mL vial to prepare a Ga precursor solution. The Ga concentration of the precursor solution is 5.68 M.

### (4) Preparation Example 4: Preparing Gallium (III) Acetylacetonate-Toluene Precursor Solution

1.67 g (4.54 mmol) of gallium (III) chloride and 16 mL of toluene were placed in 20 mL vial to prepare a Ga precursor solution. The Ga concentration of the precursor solution is 0.28 M.

### (5) Preparation Example 5: Preparing S-Oleylamine Precursor Solution

0.305 g (9.5 mmol) of S and 9.5 mL (28.5 mmol) of oleylamine were placed in a 50 mL flask, decompressed at room temperature (RT) for 30 minutes, heated to 120° C. for 10 minutes, and then reacted for 1 hour. The mixed solution was cooled to room temperature in in an Ar atmosphere to prepare an S precursor solution. The S concentration of the precursor solution is 1 M.

### (6) Preparation Example 6: Preparing AgInGaS Quantum Dot Core

1) 0.3 g of gallium (III) acetylacetonate and trioctylphosphine oxide (TOPO) prepared in Preparation Example 4, 5 ml of silver (I) iodide-oleylamine prepared in Preparation Example 1, indium (III) chloride-ethanol prepared in Preparation Example 2 and 1-octadecene are placed in a round flask of 50 mL having a refluxer and heated to 120° C. while being maintained at about 0.005 torr using a vacuum pump for 30 minutes.
2) Then, after substituting with an N₂ atmosphere, 1 ml (0.03 g, 1 mmol) of the S-oleylamine solution prepared in Preparation Example 5 and 0.5 ml of 1-dodecanethiol are injected at 120° C.
   3) After the S-oleylamine solution is added, it is maintained at 0.005 torr using a vacuum pump at 120° C. for 30 minutes. Then, the reaction is terminated after stirring at 30° C. for 10 minutes.
4) 5 ml of tris dimethylamino phosphine ((PDEA) 3) +trioctylphosphine (TOP) mixed solution is injected at 280° C. and is then cooled to room temperature.
5) The prepared AgInGaS quantum dot solution is divided into two and is filled with 42.5 ml of ethanol, preparing 50 ml of AgInGaS core-ethanol solution.
6) The solution is centrifuged at 5000 RPM for 5 minutes and then dispersed in 1.2 ml of toluene. The dispersed AgInGaS core-toluene solution is centrifuged at 5000 RPM for 1 minute to remove impurities, obtaining an AgInGaS core quantum dot solution.

### (7) Embodiment 1: Preparing AgInGaS/GaS/GaS quantum dots [In/(Ag+Ga)=0.328]

### (7-1) Embodiment 1-1: Preparing AgInGaS/GaS quantum dots

1) In the process of Preparation Example 6, an AgInGaS quantum dot core solution is prepared using 1 ml (Ag: 0.24 mmol) of silver (I) iodide-oleylamine, 2 ml (In: 0.2 mmol) of indium (III) chloride-ethanol, and 0.135 g (Ga: 0.37 mmol) of gallium (III) acetylacetonate.
2) 16 ml of oleylamine is prepared in a 50 mL 3-neck round flask with a refluxer, heated to 120° C., and maintained at 0.005 torr using a vacuum pump for 30 minutes. After substitution with a nitrogen atmosphere at 120° C., the AgInGaS quantum dot core solution of 1) is injected, 0.8 ml 0.80 g, 4.54 mmol of gallium (III) chloride-toluene solution prepared in Preparation Example 3 and 2 ml of S-oleylamine are injected, and toluene is removed using a vacuum pump. Then, after substitution with a nitrogen atmosphere, the reaction proceeds at 30° C. for 60 minutes.
3) 5 ml of tris dimethylamino phosphine (PDEA)₃)+trioctylphosphine (TOP) mixed solution is injected at 280° C. and cooled to room temperature, obtaining an AgInGaS/Gas quantum dot solution.

### (7-2) Embodiment 1-2: Preparing AgInGaS/GaS/Ga Quantum Dots

1) 16 ml of oleylamine is prepared in a 50 mL 3-neck round flask with a refluxer, heated to 120 ºC, and maintained at 0.005 torr using a vacuum pump for 30 minutes. After substitution with a nitrogen atmosphere at 120° C., the AgInGaS/Gas quantum dot solution is injected, 0.8 ml of gallium (III) chloride-toluene solution and 2 ml of S-oleylamine are injected, and toluene is removed using a vacuum pump. Then, after substitution with a nitrogen atmosphere, the reaction proceeds at 30° C. for 100 minutes.
2) 5 ml of tris dimethylamino phosphine (PDEA)₃)+trioctylphosphine (TOP) mixed solution is injected at 280° C. and cooled to room temperature, obtaining a quantum dot solution.

### (8) Embodiment 2: Preparing AgInGaS/GaS/AgGaS Quantum dots [In/(Ag+Ga)=0.328]

Quantum dots are obtained in the same manner as in embodiment 2 except that 0.014 g of silver (I) iodide is included in process 2) of embodiment 1-2 of embodiment 1.

### (9) Embodiment 3: Preparing AgInGaS/AgGaS/AgGaS Quantum Dots [In/(Ag+Ga)=0.328]

Quantum dots are obtained in the same manner as in embodiment 2 except that 0.014 g of silver(I) iodide is included in process 2) of embodiment 1-1 and embodiment 1-2 of embodiment 1.

### (10) Embodiment 4: Preparing AgInGaS/AgGaS/Gas Quantum Dots [In/(Ag+Ga)=0.328]

Quantum dots are obtained in the same manner as in embodiment 2 except that 0.014 g of silver(I) iodide is included in process 2) of embodiment 1-1 of embodiment 1.

### (11) Embodiment 5: Preparing AgInGaS/AgGaS/Gas Quantum Dots [In/(Ag+Ga)=0.365]

In the process of Preparation Example 6, an AgInGaS quantum dot core is prepared using 0.915 ml (Ag: 0.22 mmol) of silver (I) iodide-oleylamine, 2.3 ml (In: 0.23 mmol) of indium (III) chloride-ethanol, and 0.15 g (Ga: 0.41 mmol) of gallium (III) acetylacetonate, and a shell is formed on the core in the same manner as that in embodiment 4, obtaining quantum dots.

### (12) Embodiment 6: Preparing AgInGaS/AgGaS/Gas Quantum Dots [In/(Ag+Ga)=0.397]

In the process of Preparation Example 6, an AgInGaS quantum dot core is prepared using 0.9575 ml (Ag: 0.23 mmol) of silver (I) iodide-oleylamine, 2.5 ml (In: 0.25 mmol) of indium (III) chloride-ethanol, and 0.146 g (Ga: 0.4 mmol) of gallium (III) acetylacetonate, and a shell is formed on the core in the same manner as that in embodiment 4, obtaining quantum dots.

### (13) Embodiment 7: Preparing AgInGaS/AgGaS/Gas Quantum Dots [In/(Ag+Ga)=0.407]

In the process of Preparation Example 6, an AgInGaS quantum dot core is prepared using 1.67 ml (Ag: 0.4 mmol) of silver (I) iodide-oleylamine, 2.4 ml (In: 0.24 mmol) of indium (III) chloride-ethanol, and 0.0697 g (Ga: 0.19 mmol) of gallium (III) acetylacetonate, and a shell is formed on the core in the same manner as that in embodiment 4, obtaining quantum dots.

### (14) Embodiment 8: Preparing AgInGaS/AgGaS/Gas Quantum Dots [In/(Ag+Ga)=0.459]

In the process of Preparation Example 6, an AgInGaS quantum dot core is prepared using 1.92 ml (Ag: 0.46 mmol) of silver (I) iodide-oleylamine, 2.8 ml (In: 0.28 mmol) of indium (III) chloride-ethanol, and 0.055 g (Ga: 0.15 mmol) of gallium (III) acetylacetonate, and a shell is formed on the core in the same manner as that in embodiment 4, obtaining quantum dots.

### (15) Embodiment 9: Preparing AgInGaS/AgGaS/Gas Quantum Dots [In/(Ag+Ga)=0.508]

In the process of Preparation Example 6, an AgInGaS quantum dot core is prepared using 1.96 ml (Ag: 0.47 mmol) of silver (I) iodide-oleylamine, 3.1 ml (In: 0.31 mmol) of indium (III) chloride-ethanol, and 0.051 g (Ga: 0.14 mmol) of gallium (III) acetylacetonate, and a shell is formed on the core in the same manner as that in embodiment 4, obtaining quantum dots.

### (16) Embodiment 10: Preparing AgInGaS/AgGaS/GaS Quantum Dots [In/(Ag+Ga)=0.557]

In the process of Preparation Example 6, an AgInGaS quantum dot core is prepared using 2 ml (Ag: 0.48 mmol) of silver (I) iodide-oleylamine, 3.4 ml (In: 0.34 mmol) of indium (III) chloride-ethanol, and 0.047 g (Ga: 0.13 mmol) of gallium (III) acetylacetonate, and a shell is formed on the core in the same manner as that in embodiment 4, obtaining quantum dots.

### (17) Embodiment 11: Preparing AgInGaS/AgGaS/Gas Quantum Dots [In/(Ag+Ga)=0.596]

In the process of Preparation Example 6, an AgInGaS quantum dot core is prepared using 2 ml (Ag: 0.48 mmol) of silver (I) iodide-oleylamine, 3.7 ml (In: 0.37 mmol) of indium (III) chloride-ethanol, and 0.051 g (Ga: 0.14 mmol) of gallium (III) acetylacetonate, and a shell is formed on the core in the same manner as that in embodiment 4, obtaining quantum dots.

### (18) Comparative example 1: Preparing AgInGaS/GaS Quantum Dots [In/(Ag+Ga)=0.328]

Quantum dots are obtained in the same manner as in embodiment 1-1, except for the process of embodiment 1-2 in embodiment 1.

### (19) Comparative example 2: Preparing AgInGaS/GaS Quantum Dots [In/(Ag+Ga)=0.508]

In the process of Preparation Example 6, an AgInGaS quantum dot core is prepared using 1.96 ml (Ag: 0.47 mmol) of silver (I) iodide-oleylamine, 3.1 ml (In: 0.31 mmol) of indium (III) chloride-ethanol, and 0.051 g (Ga: 0.14 mmol) of gallium(III) acetylacetonate, and a shell is formed on the core in the same manner as that in comparative example 1, obtaining quantum dots.

### EXPERIMENTAL EXAMPLE

Table 1 shows the results measured by Otsuka Electronics' QE-2000 device, including the results of checking the optical characteristics [Emission Peak, Quantum Yield, Full Width at Half Maximum (FWHM)] of the prepared quantum dots.

TABLE 1

| | Configuration of AgInGaS core | | | | | | | |
|---|---|---|---|---|---|---|---|---|
| | | | | In/(Ag + Ga) | | | | |
| | Ag | In | Ga | precursor | | Emission | | |
| | precursor | precursor | precursor | composition | Configuration | peak | FWHM | QY |
| | (mol) | (mol) | (mol) | ratio | of shell | (nm) | (nm) | (%) |
| Embodiment 1 | 0.24 | 0.2 | 0.37 | 0.328 | GaS/GaS | 524 | 30 | 83 |
| Embodiment 2 | 0.24 | 0.2 | 0.37 | 0.328 | GaS/AgGaS | 524 | 30 | 85 |
| Embodiment 3 | 0.24 | 0.2 | 0.37 | 0.328 | AgGaS/GaS | 524 | 29 | 90 |
| Embodiment 4 | 0.24 | 0.2 | 0.37 | 0.328 | AgGaS/AgGaS | 524 | 30 | 88 |
| Embodiment 5 | 0.22 | 0.23 | 0.41 | 0.365 | AgGaS/GaS | 528 | 29 | 92 |
| Embodiment 6 | 0.23 | 0.25 | 0.4 | 0.397 | AgGaS/GaS | 530 | 28 | 90 |
| Embodiment 7 | 0.4 | 0.24 | 0.19 | 0.407 | AgGaS/GaS | 535 | 30 | 91 |
| Embodiment 8 | 0.46 | 0.28 | 0.15 | 0.459 | AgGaS/GaS | 545 | 35 | 88 |
| Embodiment 9 | 0.47 | 0.31 | 0.14 | 0.508 | AgGaS/GaS | 555 | 39 | 83 |
| Embodiment 10 | 0.48 | 0.34 | 0.13 | 0.557 | AgGaS/GaS | 565 | 42 | 80 |
| Embodiment 11 | 0.48 | 0.37 | 0.14 | 0.596 | AgGaS/GaS | 575 | 44 | 83 |
| Comparative | 0.24 | 0.2 | 0.37 | 0.328 | GaS | 524 | 40 | 72 |
| example 1 | | | | | | | | |
| Comparative | 0.47 | 0.31 | 0.14 | 0.508 | GaS | 555 | 42 | 71 |
| example 2 | | | | | | | | |

Table 1 shows a tendency of blue shift as the amount of the Ag precursor increases, and a tendency of red shift as the amount of In and Ga precursors increases.

It is determined that if the amount of Ag constituting the quantum dot 10 increases, the proportion of electrons constituting AgS, occupied in the valence band region of the AgInGaS core, in the bandgap structure of the AgInGaS core 12 increases, so that the overall bandgap of AgInGaS increases, leading to blue shift.

Further, it may be identified that all of the emission wavelengths are the same if the amounts of the precursors constituting the AgInGaS core 12 are the same, and the amounts of the precursors constituting the AgInGaS core 12 regardless of the configuration of the shell 14 when the results of embodiment 1 to embodiment 4 and comparative example 1 and embodiment 9 [In/(Ag+Ga)=0.328] and comparative example 2 [In/(Ag+Ga)=0.508] having different configurations of the shell 14 are compared. This indicates that the shell 14 does not affect the emission wavelength when the quantum dot 10 is configured.

It is identified that In contributes more to wavelength shift than Ag. Since the atomic number (In³⁺) of the In precursor is relatively large, the bonding contribution with the quantum dot constituent elements is high, so that it is determined that the AgInGaS quantum dot configuration of a larger size is easy. In contrast, the reason why Ag has a small contribution to wavelength shift is determined to be due to the relatively small atomic number of the Ag precursor (Ag⁺) which has a smaller contribution to the bonding of the quantum dot constituent atoms.

In the present embodiment, it may be preferable to form double shells 14 and 16 or multiple shells 14, 16, and 18 on the AgInGaS quantum dot 10 rather than a single shell 14 so as to reduce surface defects of the core 12 and contribute to enhancing luminous efficiency.

In Table 1, comparison between the results of comparative examples 1 and 2 using a single shell (GaS) and the results of embodiments 1 to 11 using double shells reveals that the quantum efficiency of the quantum dots including the double shells is further enhanced.

It is determined that the outer shell 16 that may be formed thin on the surface of the quantum dot 10 may have the largest band gap compared to the core 12 and the inner shell 14, and accordingly, the surface defects may be further suppressed, thereby enhancing the luminous efficiency of the quantum dot 10.

It has been described above that it is possible to enhance the luminous efficiency by adjusting the amounts of the Ag, In, and Ga precursors when forming an AgInGaS quantum dot core through embodiments 1 to 11 and comparative examples 1 and 2 of AgInGaS/GaS/GaS, AgInGaS/GaS/AgGaS AgInGaS/AgGaS/Gas quantum dots.

In the above-described embodiments 1 to 11, AgInGaS/GaS/GaS, AgInGaS/GaS/AgGaS AgInGaS/AgGaS/GaS quantum dots which use Ag as the group I element, Ga as the group II element, and S as the group VI element have been described as a representative example. However, AgInGaS/first shell/second shell quantum dots which use a group I element other than Ag included in the first and second shells 14 and 16, one of Al, In, and Tl other than Ga as the group III element included in the first and second shells 14 and 16, and one of Se and Te other than S as the group VI element may also enhance luminous efficiency by adjusting the amounts of Ag, In, and Ga precursors in forming the AgInGaS quantum dot core.

The above description is merely an example description of the disclosure, and various changes may be made thereto without departing from the essential features of the disclosure by one of ordinary skill in the art. Accordingly, the embodiments set forth herein are provided for illustrative purposes, but not to limit the scope of the disclosure, and should be appreciated that the scope of the disclosure is not limited by the embodiments. The scope of the disclosure should be construed by the following claims, and all technical spirits within equivalents thereof should be interpreted to belong to the scope of the disclosure.

What is claimed is:

1. A quantum dot, comprising:
a core including Ag, In, Ga, and S; and
a shell including at least one selected from among a group I element or a group III element; and a group VI element, on the core, wherein the quantum dot is capable of adjusting an emission wavelength according to a ratio of Ag, In, and Ga precursors defined by Equation 1:
$$\frac{In precursor ( mol )}{Ag precursor ( mol ) + Ga precursor ( mol )} = X \qquad [ Equation 1 ]$$
in Equation 1,
1) The amount of the precursor of each element is 0.1 mmol or more,
2) When X is 0.32 or more and less than 0.40, the quantum dot has an emission wavelength of 500 nm to 530 nm, and
3) When X is 0.40 or more and less than 0.60, the quantum dot has an emission wavelength of 531 nm to 580 nm.

2. The quantum dot of claim 1, wherein the group I element included in the shell includes at least one selected from among Li, Na, K, Rb, Cs, Cu, Ag, and Au.

3. The quantum dot of claim 1, wherein the group III element included in the shell includes at least one selected from among Al, Ga, In, and Tl.

4. The quantum dot of claim 1, wherein the group VI element included in the shell includes at least one selected from among S, Se, and Te.

5. The quantum dot of claim 1, wherein the quantum dot has a diameter of 1 nm to 20 nm.

6. The quantum dot of claim 1, wherein the shell includes:
a first shell disposed on the core and including at least one of a group I element and a group III element and a group VI element; and
a second shell disposed on the first shell and including at least one of a group I element and a group III element and a group VI element.

7. The quantum dot of claim 6, wherein each of the first shell and the second shell includes one of AgAIS, AgAlSe, AgAlTe, AgGaS, AgGaSe, AgGaTe, AgInS, AgInSe, AgInTe, AgTis, AgTiSe, AgTiTe, CuAls, CuAlSe, CuAlTe, CuGaS, CuGaSe, CuGaTe, CuInS, CuInSe, CuInTe, CuTiS, CuTiSe, CuTiTe, AuAlS, AuAlSe, AuAlTe, AuGaS, AuGaSe, AuGaTe, AuInS, AuInSe, AuInTe, AuTiS, AuTiSe, AuTiTe, Als, AlSe, AlTe, Gas, GaSe, GaTe, InS, InSe, InTe, TiS, TiSe, and TiTe.

8. A method for preparing a quantum dot, the method comprising:
a core preparing step of preparing a core by injecting and reacting an Ag precursor, an In precursor, a Ga precursor, an S precursor, and a solvent in a first reactor; and
a shell preparing step of preparing a shell by injecting and reacting the prepared core in a second reactor containing at least one selected from among a group I precursor including a group I element or a group III precursor including a group III element and a group VI precursor including a group VI element, wherein the quantum dot is capable of adjusting an emission wavelength according to a ratio of Ag, In, and Ga precursors defined by Equation 1:
$$\frac{In precursor ( mol )}{Ag precursor ( mol ) + Ga precursor ( mol )} = X \qquad [ Equation 1 ]$$
in Equation 1,
1) The amount of the precursor of each element is 0.1 mmol or more,
2) When X is 0.32 or more and less than 0.40, the quantum dot has an emission wavelength of 500 nm to 530 nm, and
3) When X is 0.40 or more and less than 0.60, the quantum dot has an emission wavelength of 531 nm to 580 nm.

9. An electronic device, comprising:
a display device including a light emitting diode including the quantum dot of claim 1; and
a controller driving the display device.
